(19) United States
(12) Patent Application Publication
(10) Pub. No.: US 2022/0277797 A1
(43) Pub. Date: Sep. 1, 2022

(54) AUTHENTICATED SIGNALS FOR WRITE PROTECTION

(71) Applicant: Hewlett-Packard Development Company, L.P., Spring, TX (US)

(72) Inventors: Kai-Chun Tai, Taipei City (TW); Super Liao, Taipei City (TW); Thong Thai, Spring, TX (US)

(73) Assignee: Hewlett-Packard Development Company, L.P., Spring, TX (US)

(21) Appl. No.: 17/633,246

(22) PCT Filed: Oct. 10, 2019
(86) PCT No.: PCT/US2019/055597

§ 371 Date: Feb. 7, 2022

(51) Int. Cl. G11C 16/22; G11C 16/10; G11C 16/32; H03K 19/20

(52) U.S. Cl. CPC G11C 16/22; G11C 16/105; G11C 16/32; H03K 19/20

(57) ABSTRACT

An electronic device comprises circuitry to generate and authenticate a first write protect (WP) signal; a controller to write data to a memory, the controller to generate a second WP signal; and a logic gate coupled to the circuitry and the controller. The logic gate is to receive the first and second WP signals; generate a third WP signal based on the first and second WP signals; and assert the third WP signal to the memory to control a write enable state of the memory.

### BACKGROUND

Electronic devices (e.g., notebooks, tablets) include printed circuit boards (PCBs) that contain circuitry to drive a display (e.g., a liquid crystal display (LCD)). The PCB may include a controller that drives the display and a memory that stores information usable to the controller in driving the display. For example, the memory may store timing data for driving individual components of the display, color data, etc.

### BRIEF DESCRIPTION OF THE DRAWINGS

Various examples will be described below referring to the following figures:

FIG. 1 depicts a block diagram of an electronic device implementing authenticated signals for write protection of a memory, in accordance with various examples.

FIG. 2 depicts a logic gate for write protection of a memory, in accordance with various examples.

FIG. 3 depicts another logic gate for write protection of a memory, in accordance with various examples.

FIG. 4 depicts another logic gate for write protection of a memory, in accordance with various examples.

FIG. 5 depicts a flow diagram of a method for using authenticated signals for write protection of a memory, in accordance with various examples.

### DETAILED DESCRIPTION

As explained above, electronic devices (e.g., notebooks, tablets) include printed circuit boards (PCBs) that contain circuitry to drive a display (e.g., a liquid crystal display (LCD)). The PCB may include a controller that drives the display and a memory that stores information usable to the controller in driving the display. For example, the memory may store timing data for driving individual components of the display, color data, etc.

The controller may write to and read from the memory. Such systems may further include a main system board that provides data and instructions to the controller on the PCB. A controller on the main system board may instruct the controller on the PCB to perform various functions, including writing data to the memory on the PCB, via an interface that is susceptible to hacking.

The memory may include a write protect (WP) feature that prevents the controller on the PCB from writing to the memory unless a WP input on the memory has been asserted. The controller on the PCB controls the WP input as instructed by the controller on the main system board. However, because the interface between the two controllers is susceptible to hacking, the WP input can be manipulated and undesirable data can be written to the memory.

This disclosure describes a display system that protects against hacking of a memory WP input and of signals used to control the WP input. The display system may comprise a first circuit board, a second circuit board, and a display. The second circuit board includes a controller to drive the display, a memory usable by the controller to drive the display, and a logic gate to drive a WP input of the memory that enables and disables a write protection feature of the memory. The first circuit board includes circuitry to interact with and control the circuitry on the second circuit board. The circuitry on both the first and second circuit boards generate WP signals that are input to the logic gate on the second circuit board, with the WP signal generated by the first circuit board being an authenticated WP signal that is resistant to hacking. The output of the logic gate couples to and controls the WP input of the memory that is on the second circuit board. Because the memory WP input is controlled in part by the authenticated WP signal, the memory WP input is resistant to tampering.

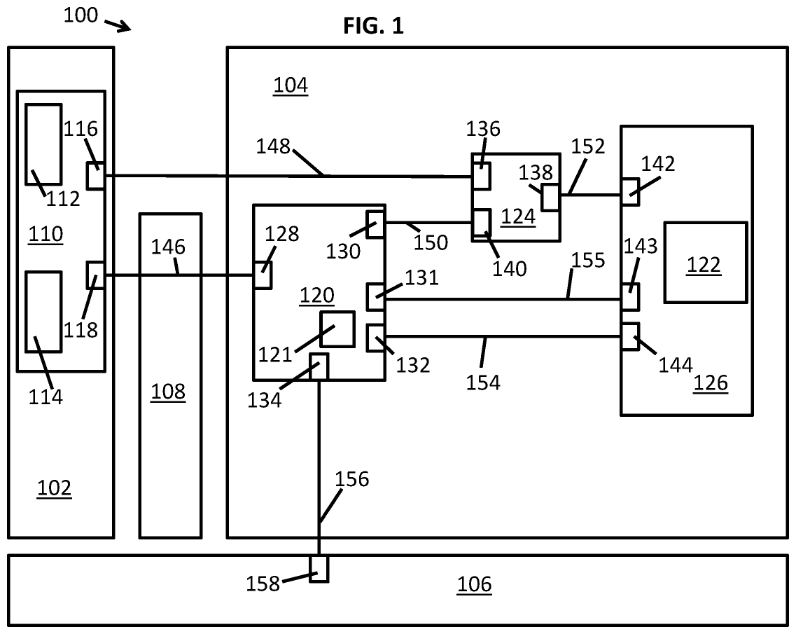

FIG. 1 depicts a block diagram of an electronic device 100 implementing authenticated signals for write protection of a memory, in accordance with various examples. In some examples, the electronic device 100 is a personal computing device, such as a desktop computer, a laptop computer, a notebook, a tablet, etc. In some examples, the electronic device 100 is a display device, such as a television display, a computer display, a point-of-sale display, etc. Other types of electronic devices are contemplated and fall within the scope of this disclosure.

In some examples, the electronic device 100 includes a single circuit board. In some examples, the electronic device 100 includes multiple circuit boards. Although the components described herein may be configured as desired for use with any number of circuit boards, the disclosed examples assume the use of two circuit boards 102 and 104. The circuit board 102 may be, for example, a motherboard. In some examples, the circuit board 104 is a motherboard. As explained above, in some examples, the components are disposed on a single circuit board (e.g., motherboard), and in some examples, the components are disposed on multiple circuit boards.

The circuit board 102 has arranged thereupon a controller (e.g., an embedded controller, or EC) 110. The controller 110 includes executable instructions 112 and 114 that the controller 110 executes to perform some or all of the actions attributed herein to the controller 110. In some examples, the executable instructions 112 may comprise firmware. In some examples, the executable instructions 114 may comprise an authentication engine to authenticate the executable instructions 112, and the authenticated executable instructions 112, in turn, are usable to generate authenticated write protect (WP) signals, as described below. In some examples, the executable instructions 112, 114 are stored in a memory (not expressly shown) separate from the controller 110 but accessible to the controller 110 for execution. In addition to the executable instructions 112, 114, the controller 110 includes a WP output 116 and an input/output (I/O) 118. The controller 110 outputs authenticated WP signals on a connection 148 via the WP output 116, and the controller 110 sends and receives data signals, clock signals, command signals, and other suitable signals on the connection 146 via the I/O 118. In some examples, the controller 110 provides commands to the controller 120 via the connection 146, for example, a command to write data to a memory 126, along with data to be written.

The executable instructions 114 may authenticate the executable instructions 112 using any suitable process. For example, the executable instructions 114, when executed by the controller 110, may cause the controller 110 to first verify a signature (or hash, key, or equivalent) encoded in the executable instructions 112. For instance, the controller 110, while executing the executable instructions 114, may compare the signature of the executable instructions 112 to a private signature (or hash, key, or equivalent) encoded in the executable instructions 114. If the signature of the executable instructions 112 is verified, the executable instructions 112 are considered to be authenticated. The controller 110 may then generate an authenticated WP signal (e.g., asserted WP signal) on the connection 148 by execution of the authenticated executable instructions 112.

The circuit board 104 includes a controller 120. In some examples, the controller 120 includes a timing controller (e.g., a T-CON controller) that is to drive a display 106. For instance, the controller 120 may generate horizontal and vertical timing panel signals, panel bias signals, panel enable signals, etc. The controller 120 includes I/Os 128, 131, 132, and 134. The controller 120 also includes a WP output 130. The I/O 128 couples to the I/O 118 via connection 146, which passes through an interface (e.g., an auxiliary, or AUX, interface) 108 that is a multi-purpose interface usable for display control, the transmission of auxiliary data, instructing timing controllers (e.g., T-CON), writing data to memory, etc. In some examples, the connection 148 may pass through the interface 108, but in other examples, the connection 148 does not pass through the interface 108. The I/O 134 couples to an I/O 158 of the display 106 via a connection 156. In this manner, the display 106 receives driving signals from the controller 120, and the controller 120 may receive information, such as status signals, from the display 106. The I/O 131 couples to a connection 155, and the I/O 132 couples to a connection 154. The WP output 130 couples to a connection 150 on which the controller 120 may output a WP signal. The controller 120 comprises executable instructions 121 which, when executed by the controller 120, cause the controller 120 to perform some or all of the actions attributed herein to the controller 120. In some examples, the executable instructions 121 are located elsewhere, e.g., on the memory 126, or on another memory coupled to the controller 120.

The circuit board 104 further includes the memory 126, such as a volatile or non-volatile memory (e.g., electrically erasable programmable read-only memory (EEPROM)). The memory 126 stores data 122, such as data that is usable by the controller 120 to drive the display 106. Such data 122 may include, e.g., timing data, display data, clock data, and any of a variety of other types of data. The memory 126 includes a WP input 142, an I/O 143, and an I/O 144. The WP input 142 couples to a connection 152, the I/O 143 couples to the controller 120 via the connection 155, and the I/O 144 couples to the controller 120 via the connection 154. In some examples, the memory 126 is write-protectable, meaning that the memory 126 is not writeable unless a write protection feature of the memory 126 is disabled. The WP input 142 controls the write protection feature of the memory 126. In some examples, when the connection 152 provides a HIGH signal to the WP input 142, the write protection feature of the memory 126 is disabled. In some examples, when the connection 152 provides a LOW signal to the WP input 142, the write protection feature of the memory 126 is enabled. The remainder of this disclosure assumes that the write protection feature of the memory 126 is disabled when the connection 152 provides a HIGH signal to the WP input 142.

The connection 155, in some examples, comprises a serial peripheral interface and carries, e.g., data, clock signals, etc., between the controller 120 and the memory 126. In some examples, the connection 154 carries data and clock signals for debugging purposes between the controller 120 and the memory 126. The controller 120 generates the aforementioned WP signal in any suitable manner and outputs the WP signal on the connection 150. In some examples, the controller 120 generates the WP signal in response to a command received from the controller 110 via connection 146 that the controller 120 is to write data to the memory 126. In this situation, the controller 120 first attempts to disable the write protection feature of the memory 126 by outputting a HIGH WP signal on the connection 150, and then the controller 120 writes the data to the memory 126 via the connection 155.

In some examples, either of the WP signals on connections 148, 150 may be provided directly to the WP input 142. For instance, the WP signal on connection 148 may be provided to the WP input 142, thus making the WP signal from the controller 110 the determinant of whether the write protection feature of the memory 126 is enabled or not. Similarly, in other instances, the WP signal on connection 150 may be provided to the WP input 142, thus making the WP signal from the controller 120 the determinant of whether the write protection feature of the memory 126 is enabled or not. In some examples, however, both WP signals on the connections 148, 150 determine the status of the WP signal on connection 152, which drives the WP input 142. For instance, in some examples, the circuit board 104 may include a logic gate 124 having WP inputs 136, 140 and a WP output 138. The WP inputs 136, 140 couple to the connections 148, 150, respectively, and the WP output 138 couples to the WP input 142 via the connection 152.

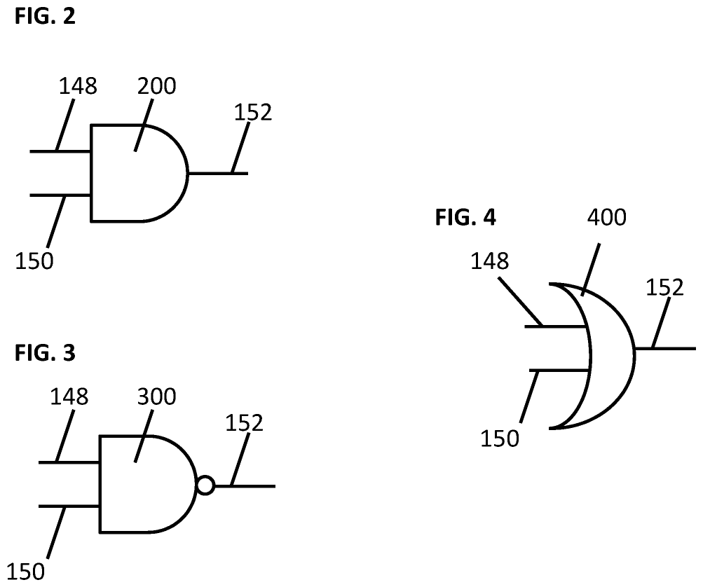

In some examples, the logic gate 124 is an AND gate 200, as FIG. 2 depicts. In such examples, the connections 148, 150 are coupled to the inputs of the AND gate 200 and the connection 152 is coupled to the output of the AND gate 200. Thus, the WP signal on connection 152 is not asserted (and the write protection feature of memory 126 is not disabled) unless both the WP signals on connections 148, 150 are asserted. In some examples, the logic gate 124 is a NAND gate 300, as FIG. 3 depicts. In such examples, the connections 148, 150 are coupled to the inputs of the NAND gate 300 and the connection 152 is coupled to the output of the NAND gate 300. When a NAND gate 300 is used as the logic gate 124, the write protection feature of the memory 126 is not disabled unless the WP signal to the WP input 142 is HIGH, meaning that the signals on connections 148, 150 should be LOW. Thus, when the signals on connections 148, 150 are LOW, the WP signal on connection 152 is HIGH, thereby disabling the write protection feature of the memory 126.

In some examples, the logic gate 124 is an OR gate 400, as FIG. 4 depicts. In such examples, the connections 148, 150 are coupled to the inputs of the OR gate 400 and the connection 152 is coupled to the output of the OR gate 400. When an OR gate 400 is used as the logic gate 124, the write protection feature of the memory 126 is not disabled unless the WP signal to the WP input 142 is LOW, meaning that the signals on connections 148, 150 should be LOW. Thus, when the signals on connections 148, 150 are LOW, the WP signal on connection 152 is LOW, thereby disabling the write protection feature of the memory 126. Various other implementations are contemplated and included in the scope of this disclosure, for example, with various combinations of logic gates (e.g., combinations of AND, NAND, and/or OR gates) and inverters to accommodate different binary WP signaling schemes among the controllers 110, 120 and the memory 126. Any and all such combinations may be used to facilitate the provision of a particular signal status to the WP input 142, either to enable or disable the write protection feature of memory 126.

Referring now to FIGS. 1 and 2, in an example operation that assumes an AND gate 200 for the logic gate 124, data is to be written to the memory 126. The controller 110 provides the data to be written, along with any appropriate commands, to the controller 120 via connection 146. The controller 110 also asserts the authenticated WP signal on the connection 148. The controller 120 receives the data and commands from the controller 110. In response, the controller 120 asserts the WP signal on the connection 150. The logic gate 124 (e.g., an AND gate) receives the two asserted WP signals and outputs an asserted WP signal on the connection 152. As a result, the write protection feature of the memory 126 is disabled. The controller 120 writes the data received from the controller 110, and/or any other data, to the memory 126 while the write protection feature is disabled. Once the data write operation is complete, the controller 120 may deassert the WP signal on connection 150, which enables the write protection feature of memory 126. Alternatively or in addition, the controller 120 communicates completion of the write operation to the controller 110, which, in response, deasserts the WP signal on the connection 148, thereby enabling the write protection feature of the memory 126. The controller 120 may then read from the data 122 on memory 126 as it drives the display 106.

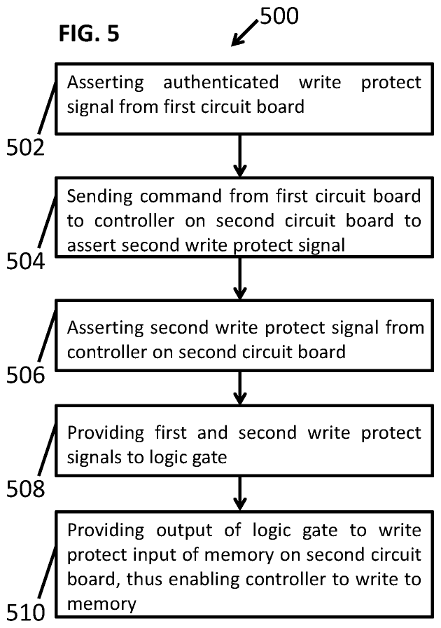

FIG. 5 depicts a flow diagram of a method 500 for using authenticated signals for write protection of a memory, in accordance with various examples. The method 500 begins with asserting an authenticated write protect signal from the first circuit board (502). For example, the controller 110 on the circuit board 102 may assert an authenticated WP signal on the connection 148 as described above. The method 500 continues with sending a command from the first circuit board to a controller on a second circuit board to assert a second WP signal (504). For example, the controller 110 on the circuit board 102 may send a command to the controller 120 on the circuit board 104 to assert the WP signal on the connection 150. The method 500 continues with asserting the second WP signal from the controller on the second circuit board (506). For example, the controller 120 may assert the WP signal on connection 150. The method 500 continues with providing the first and second WP signals to a logic gate (508). For example, the WP signals from the controllers 110, 120 may be provided to the logic gate 124. The method 500 continues with providing an output of the logic gate to a WP input of a memory on the second circuit board, thus enabling the controller to write to the memory (510). For example, the logic gate 124 outputs a WP signal to the WP input 142 of the memory 126. In this way, the write protection feature of the memory 126 is disabled, and the controller 120 may then write to the memory 126 as desired. After the write operation is complete, one or both of the WP signals input to the logic gate 124 may be deasserted, thus again write-protecting the memory 126.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An electronic device, comprising:
circuitry to generate and authenticate a first write protect (WP) signal;
a controller to write data to a memory, the controller to generate a second WP signal; and
a logic gate coupled to the circuitry and the controller, the logic gate to:
receive the first and second WP signals;
generate a third WP signal based on the first and second WP signals; and
assert the third WP signal to the memory to control a write enable state of the memory.

2. The electronic device of claim 1, wherein the memory comprises an electrically erasable programmable read-only memory (EEPROM).

3. The electronic device of claim 1, wherein the logic gate comprises an AND gate.

4. The electronic device of claim 1, wherein the logic gate comprises a NAND gate, an OR gate, or a combination thereof.

5. The electronic device of claim 1, wherein the electronic device comprises a first circuit board on which the circuitry is located, and wherein the electronic device comprises a second circuit board on which the controller and the logic gate are located.

6. The electronic device of claim 1, comprising a display coupled to the controller, the controller to drive the display using data stored in the memory.

7. The electronic device of claim 1, wherein the circuitry includes a second controller and an authentication engine, the second controller and the authentication engine to authenticate the first WP signal.

8. The electronic device of claim 1, wherein the memory is to block attempts to write data to the memory unless the third WP signal has a particular status.

9. An electronic device, comprising:
a first circuit board comprising a first controller to provide an authenticated first write protect (WP) signal on a first WP output; and
a second circuit board, comprising:
a second controller to drive a display, the second controller to provide a second WP signal on a second WP output;
a logic gate comprising an AND gate, a NAND gate, an OR gate, or a combination thereof, the logic gate coupled to the first and second WP outputs; and
a memory including a WP input coupled to the logic gate.

10. The electronic device of claim 9, wherein the memory is to store data usable by the second controller to drive the display.

11. The electronic device of claim 9, wherein the first circuit board comprises an authentication engine usable by the first controller to authenticate the first WP signal.

12. An electronic device, comprising:
a controller to:
provide data to a timing controller coupled to the controller;
generate an authenticated write protect (WP) signal; and
provide the authenticated WP signal to control a write enable state of a memory coupled to the timing controller, the write enable state controlling whether the data is writable by the timing controller to the memory.

13. The electronic device of claim 12, comprising an authentication engine usable to authenticate the WP signal.

14. The electronic device of claim 12, comprising a logic gate to receive the authenticated WP signal, wherein the logic gate comprises one of an AND gate, a NAND gate, an OR gate, or a combination thereof.

15. The electronic device of claim 12, wherein the controller is located on a circuit board independently of the timing controller and the memory.
